(19) United States
(12) Patent Application Publication
(10) Pub. No.: US 2007/0113149 A1
(43) Pub. Date: May 17, 2007

(54) Power savings technique for iterative decoding

(75) Inventors: Stephen E. Krafft, Los Angeles, CA (US); Daniel Richard, Pasadena, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 11/586,716

(22) Filed: Oct. 26, 2006

Related U.S. Application Data
(60) Provisional application No. 60/730,022, filed on Oct. 26, 2005.

(51) Int. Cl. H03M 13/00

(52) U.S. Cl. 714/760

(57) ABSTRACT

An apparatus and method for reducing an average power consumed by an iterative decoder. A power savings loop coupled to the iterative decoder includes an averager, a comparator and an integrator. The averager receives an iteration count from the iterative decoder and determines an average iteration count of the iterative decoder. The comparator compares the average iteration count to a threshold. The threshold corresponds to a noise level that exceeds a level of noise associated with a quasi-error free (QEF) operating point of the iterative decoder. When the average iteration count exceeds the threshold, the integrator produces an output signal that lowers the maximum number of permissible iterations the iterative decoder can conduct. As a result, the average iteration count is lowered, thereby reducing the average power consumed by the iterative decoder.

### CROSS-REFERENCE TO RELATED APPLICATIONS

This application claims benefit to U.S. Provisional Patent Application No. 60/730,022, filed Oct. 26, 2005, which is incorporated herein by reference in its entirety.

### BACKGROUND OF THE INVENTION

1. Field of the Invention

The present invention generally relates to iterative decoders. More specifically, the present invention relates to power consumption within iterative decoders.

2. Background Art

Home satellite receivers are typically power hungry devices. In turn, the thermal management of a printed circuit board (PCB) containing a satellite receiver is a critical issue.

A power intensive component of the satellite receiver is the decoder. The decoder implements an iterative decoding scheme to decode blocks of data encoded according to a forward error correction (FEC) code. The average power consumed by the decoder increases with the number of iterations implemented within the decoder. Some blocks need only a few iterations while others need a large number of iterations to converge towards an acceptable number of errors.

When a block of data is highly corrupted by noise, the iterative decoder will produce a decoded block having errors despite conducting the maximum number of possible iterations. Execution of the maximum number of iterations consumes a large amount of power. Further, allowing the execution of a large number of iterations to produce a decoded block having errors is inefficient, particularly when the decoder is operating at an excessive noise level.

What is needed, therefore, is a method and system to reduce the average power consumed by an iterative decoder. More particularly, what is needed is a power savings technique for an iterative decoder to limit the number of iterations implemented by the decoder when the decoder is operating below it's quasi-error free (QEF) point.

### BRIEF SUMMARY OF THE INVENTION

Consistent with the principles of the present invention, as embodied and broadly described herein, the present invention includes a power control loop for an iterative decoder. The power control loop includes an averaging device to produce an average iteration count of the iterative decoder and an adder to compare the average iteration count to a threshold. An integrator adjusts a maximum permissible iteration count of the iterative decoder based on an output of the adder.

In the embodiment above, a comparator compares the average iteration count to a threshold. The threshold number of iterations corresponds to a number of iterations required at a noise level that exceeds a level of noise associated with a quasi-error free (QEF) operating point of the iterative decoder. At a QEF operating point, the decoder operates at a number of iterations that substantially eliminates errors. When the average iteration count exceeds the threshold, the integrator produces an output signal that lowers the maximum number of permissible iterations the iterative decoder can conduct. As a result, the average iteration count is lowered, thereby reducing the average power consumed by the iterative decoder.

Additional features and advantages of the invention will be set forth in the description that follows, and in part will be apparent from the description, or may be learned by practice of the invention. The advantages of the invention will be realized and attained by the structure and particularly pointed out in the written description and claims hereof as well as the appended drawings.

It is to be understood that both the foregoing general description and the following detailed description are exemplary and explanatory and are intended to provide further explanation of the invention as claimed.

### BRIEF DESCRIPTION OF THE FIGURES.

The accompanying drawings illustrate the present invention and, together with the description, further serve to explain the principles of the invention and to enable one skilled in the pertinent art to make and use the invention.

FIG. 1 illustrates a decoding system of the present invention;

FIG. 2 illustrates a closed loop representation of a power savings loop of the present invention depicted in FIG. 1;

FIG. 3 illustrates a performance of the power savings loop of the present invention at a first loop bandwidth setting;

FIG. 4 illustrates a performance of the power savings loop of the present invention at a second loop bandwidth setting;

FIG. 5 illustrates a performance of the power savings loop of the present invention at a third loop bandwidth setting;

FIG. 6 illustrates a performance of the power savings loop of the present invention at a fourth loop bandwidth setting;

FIG. 7 illustrates a performance of the power savings loop of the present invention at a fifth loop bandwidth setting;

FIG. 8 illustrates an excess circuit of the present invention operating in conjunction with a power savings loop of the present invention; and

FIG. 9 is a flow diagram of an exemplary method of practicing an embodiment of the present invention.

### DETAILED DESCRIPTION OF THE INVENTION

The following detailed description of the present invention refers to the accompanying drawings that illustrate exemplary embodiments consistent with this invention. Other embodiments are possible, and modifications may be made to the embodiments within the spirit and scope of the invention. Therefore, the following detailed description is not meant to limit the invention. Rather, the scope of the invention is defined by the appended claims.

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

It would be apparent to one skilled in the art that the present invention, as described below, may be implemented in many different embodiments of hardware and/or the entities illustrated in the drawings. Thus, the operation and behavior of the present invention will be described with the understanding that modifications and variations of the embodiments are possible, given the level of detail presented herein.

Satellite receivers are used in home media delivery systems (e.g., set-top boxes) and home data communication systems (e.g., satellite modems). Home satellite receivers are typically power hungry devices. As noted above, the thermal management of a printed circuit board (PCB) containing a satellite receiver is a critical issue.

A power intensive component of the satellite receiver is the decoder. The decoder implements an iterative decoding scheme to decode blocks of data encoded according to a forward error correction (FEC) code. The number of iterations needed to successfully decode a block of data roughly follows a Gaussian distribution. Some blocks need only a few iterations while others need a large number of iterations to converge to an acceptable number of errors. Blocks that require a large number of iterations to converge are typically highly corrupted by noise. By adaptively restricting the maximum number of iterations that is performed on highly corrupted blocks, the average number of iterations is driven down thereby reducing the power consumed by the decoder. In addition to reducing power consumption, this mechanism may also facilitate increasing the average speed of data blocks processing thus facilitating faster bidirectional communication in certain cases, and also may reduce the average number of data blocks that require to be buffered.

The maximum number of iterations the decoder is capable of implementing on any given block is a function of the design of the decoder. Specifically, the speed of the decoder and operating costs influence the maximum possible iteration count. The operating point or quasi-error free (QEF) point of the decoder is the maximum noise level at which the decoder is expected to decode substantially error-free blocks. At the QEF point, some corrupted blocks require the maximum number of iterations to converge while others do not. The average number of iterations needed at the QEF point of the decoder is roughly half of the maximum possible iteration count.

When the noise level exceeds the QEF point, there is a substantially lowered expectation of the decoder to decode error-free blocks. Accordingly, the decoder can implement the maximum number of possible iterations and still produce errors. Execution of the maximum number of iterations consumes a significantly high amount of power. Further, permitting the execution of a large number of iterations to produce a decoded block having errors is inefficient, particularly when the decoder is operating a noise level that exceeds the QEF point.

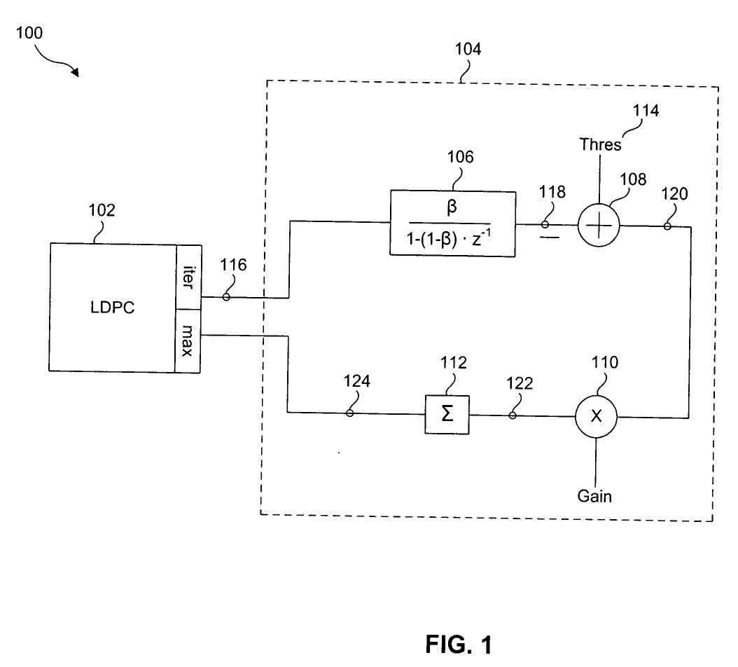

FIG. 1 illustrates a decoding system 100 that efficiently regulates a number of iterations conducted to conserve power. The decoding system 100 includes an iterative decoder 102 and a power savings loop 104. The power savings loop 104 includes an averager 106, an adder 108, a programmable gain device 110 and an integrator 112.

The decoding system 100 can be implemented in any receiver such as, for example, a digital satellite receiver. The decoder 102 iteratively decodes blocks of data according to an iterative decoding scheme. The decoder 102 is shown to be a low-density parity-check (LDPC) decoder but can be any type of iterative decoder including, for example, a turbo code soft-input soft-output (SISO) decoder.

As shown in FIG. 1, the averager 106 is coupled to an output of the iterative decoder 102. Specifically, the averager 106 is coupled to an output signal 116 that provides an indication of the number of iterations implemented by the decoder 102 on a given block. The output signal 116 can therefore be considered to provide an iteration count. The averager 106 uses the number of iterations reported by the decoder 102 to determine an average number of iterations implemented by the decoder 102. An output 118 (i.e., the average iteration count) of the averager 106 is compared to a threshold 114 to generate a difference signal 120.

The difference signal 120 is applied to the programmable gain device 110. The programmable gain device 110 amplifies the difference signal 120. Consequently, the programmable gain device 110 determines how quickly the power savings loop 104 responds to the difference signal 120. An output 122 of the programmable gain device 110 is provided to the integrator 112. In one embodiment, the programmable gain device 110 may be replaced with a multiplier. The integrator 112 generates an output 124. The output 124 is the overall output of the power savings loop 104. Specifically, the integrator output 124 is the maximum number of iterations allowed. That is, the output 124 sets the maximum number of permissible iterations that the decoder 102 can implement. The maximum number of permissible iterations can vary between zero and the maximum number of possible iterations of the iterative decoder 102.

During operation of the decoding system 100, the decoder 102 reports the number of iterations used to decode a given block (i.e., the output 116) to the power savings loop 104. The power savings loop 104 averages the number of iterations conducted and compares the average value 118 to the threshold 114. The range of blocks used to determine the average 118 is programmable. To do so, the averager 106 can comprise an integrator having a time constant.

If the average 118 is greater than the threshold 114, then the power savings loop 104 is fully activated. Specifically, the power savings loop 104 generates and applies the output 124 to the decoder 102. The output 124 lowers the maximum number of allowable iterations to some number or level that is less than the maximum number of iterations that are possible. The maximum number of allowable iterations is reduced low enough and/or reduced long enough to bring the average number of iterations 118 back down to a desired level (i.e., less than or equal to the threshold 114).

At startup, the power savings loop 104 is deactivated. Consequently, the decoder 102 is allowed to implement the maximum number of possible iterations on any given block if necessary (e.g, 60 iterations). The decoder 102 is allowed to implement the maximum number of iterations so long as the average number of iterations 118 does not exceed the specified threshold 114 (e.g., 30 iterations). The threshold 114 can be set at a level that indicates operation below the QEF point of the decoder 102. That is, the threshold 114 can be set so that the average 118 will exceed the threshold 114 when the decoder 102 receives blocks corrupted by large amounts of noise (i.e., have a large number or errors). For example, the threshold 114 can be set equal to the average number of iterations conducted by the decoder 102 at the QEF point.

When the threshold 114 is exceeded, the power savings loop 104 is activated. Since implementing the maximum number of iterations is futile for severely corrupted blocks, the maximum number of allowed iterations 124 is lowered by the power savings loop 104 so that unnecessary iterations are not executed. Accordingly, power is conserved and the average power consumed by the decoder 102 is reduced.

Over time, the average number of iterations conducted 118 will decrease as the power savings loop 104 pulls down the maximum number of permissible iterations 124. As the average 118 is reduced and returns to an acceptable level, the output 124 of the power savings loop 104 can slowly raise the maximum number of iterations allowed back to an initial setting.

Overall, the power savings loop 104 allows the maximum number of iterations to be performed at the QEF point. Below the QEF point, however, the power savings loop 104 operates to limit the number of iterations that can be performed. As a result, the power savings loop 104 operates to reduce the average power consumption of the decoder 102. Reliability of the decoder 102 is thereby improved. Further, the satellite receiver in which the decoding system 100 operates is subjected to less stringent thermal requirements. Additionally, the decoding performance of the iterative decoder 102 is not adversely affected.

The average number of iterations 118 performed by the decoder 102 is inversely proportional to the signal-to-noise ratio (SNR) of a block of encoded data. Therefore, the power savings loop 104 is activated when received SNR is low. The power savings loop 104 uses the average iterations calculation 118 as an indicator of SNR. Alternatively, the power savings loop 104 can use a measurement of SNR, either exclusively or in conjunction with the average number of iterations indicator 118, to regulate the maximum number of permissible iterations 124 as described above.

The power savings loop 104 can be implemented in hardware, software, or some combination thereof. As shown in FIG. 1, the power savings loop 104 is depicted as a digital control loop having two poles. Specifically, the averager 106 introduces a first pole into the control loop and the integrator 112 introduces a second pole into the control loop.

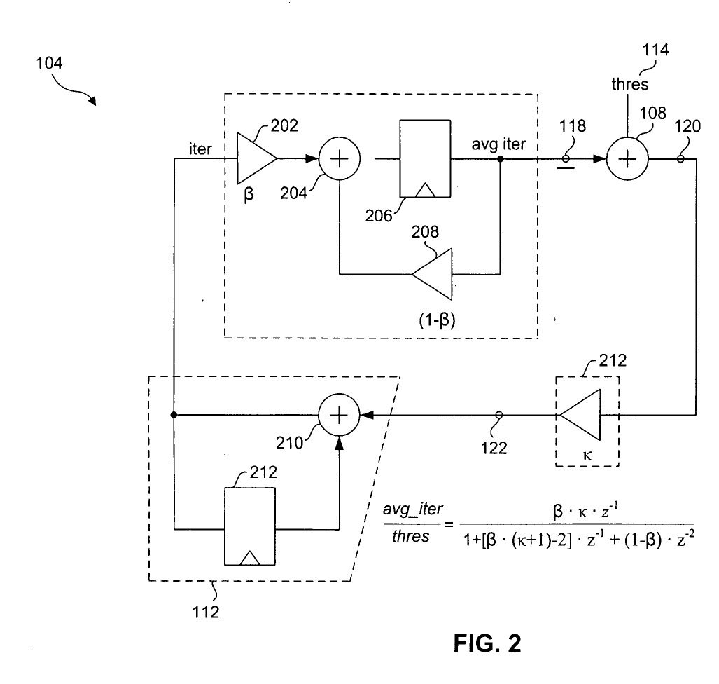

FIG. 2 illustrates exemplary hardware used to implement the power savings loop 104. Further, FIG. 2 provides a closed loop representation of the power savings loop 104. The averager 106 includes a first multiplier 202, an adder 204, a register 206 and a second multiplier 208. The integrator 112 includes an adder 210 and a register 212. The registers 206 and 212 operate as delays. The programmable gain device 110 is shown as a multiplier in FIG. 2 for consistency.

In FIG. 2, “β” represents an average time constant while “κ” represents a gain factor. Together, β and κ determine a loop bandwidth of the power savings loop 104. Both variables can be adjusted for operation. From FIG. 2, a relationship between the average number of iterations (“avg_iter”) 118 and the threshold (“thres”) 114 can be determined and represented mathematically as:

$$\frac{avg\_iter}{thres} = \frac{β \cdot κ \cdot {z}^{- 1}}{1 + [ β \cdot ( κ + 1 ) - 2 ] \cdot {z}^{- 1} + ( 1 - β ) \cdot {z}^{- 2}} \qquad ( Eq . 1 )$$

where z is a complex variable.

Eq. 1 provides a digital or discrete time representation of the transfer function of the power savings loop 104. To aid in the analysis of the power savings loop 104 and to help determine the settings for β and κ, a continuous time or S-domain representation of Eq. 1 can be determined.

As previously mentioned, the power savings loop 104 is a two pole control loop. In the S-domain, a second order loop can be represented in general as:

$$H ( s ) = \frac{out}{in} = \frac{{ω}_{n}^{2} + 2 \cdot ζ \cdot {ω}_{n} \cdot s}{{ω}_{n}^{2} + 2 \cdot ζ \cdot {ω}_{n} \cdot s + {s}^{2}} \qquad ( Eq . 2 )$$

where ωₙ represents an undamped natural frequency and ζ represents a damping ratio. By using the bilinear transform, a digital domain representation of Eq. 2 can be found and represented as:

$$\begin{matrix}H ( {z}^{- 1} ) = \frac{\begin{matrix}{( {ω}_{n} \cdot T )}^{2} + 4 \cdot ζ \cdot {ω}_{n} \cdot T + 2 \cdot {( {ω}_{n} \cdot T )}^{2} \cdot {z}^{- 1} + \\ [ {( {ω}_{n} \cdot T )}^{2} - 4 \cdot ζ \cdot {ω}_{n} \cdot T ] \cdot {z}^{- 2}\end{matrix}}{\begin{matrix}4 + {( {ω}_{n} \cdot T )}^{2} + 4 \cdot ζ \cdot {ω}_{n} \cdot T + [ 2 \cdot {( {ω}_{n} \cdot T )}^{2} - 8 ] \cdot {z}^{- 1} + \\ [ 4 + {( {ω}_{n} \cdot T )}^{2} - 4 \cdot ζ \cdot {ω}_{n} \cdot T ] \cdot {z}^{- 2}\end{matrix}} \\ where \text{:} & ( Eq . 3 ) \\ ( s = \frac{2}{T} \frac{1 - {z}^{- 1}}{1 + {z}^{- 1}} ) & ( Eq . 4 )\end{matrix}$$

and T represents a symbol period. By matching the poles of the continuous time transfer function (i.e., Eq. 3) and the discrete time transfer function (i.e., Eq. 1), the damping coefficient ζ and natural frequency ωₙ can be mapped to the time constant β and gain factor κ. Specifically, from Eqs. 1 and 3 it follows that:

$$\begin{matrix}β = \frac{4 \cdot ζ \cdot π \cdot ( \frac{{f}_{n}}{{f}_{s}} )}{1 + 2 \cdot ζ \cdot π \cdot ( \frac{{f}_{n}}{{f}_{s}} ) + {π}^{2} \cdot {( \frac{{f}_{n}}{{f}_{s}} )}^{2}} & ( Eq . 5 ) \\ κ = ( \frac{π}{ζ} ) \cdot ( \frac{{f}_{n}}{{f}_{s}} ) \\ where \text{:} & ( Eq . 6 ) \\ {ω}_{n} = 2 \cdot π \cdot {f}_{n} & ( Eq . 7 ) \\ T = \frac{1}{{f}_{s}} & ( Eq . 8 )\end{matrix}$$

From Eqs. 5-8 it is possible to set fₙ, fₛ, and ζ to determine the β and κ needed to implement the power savings loop 104 as depicted in FIG. 2.

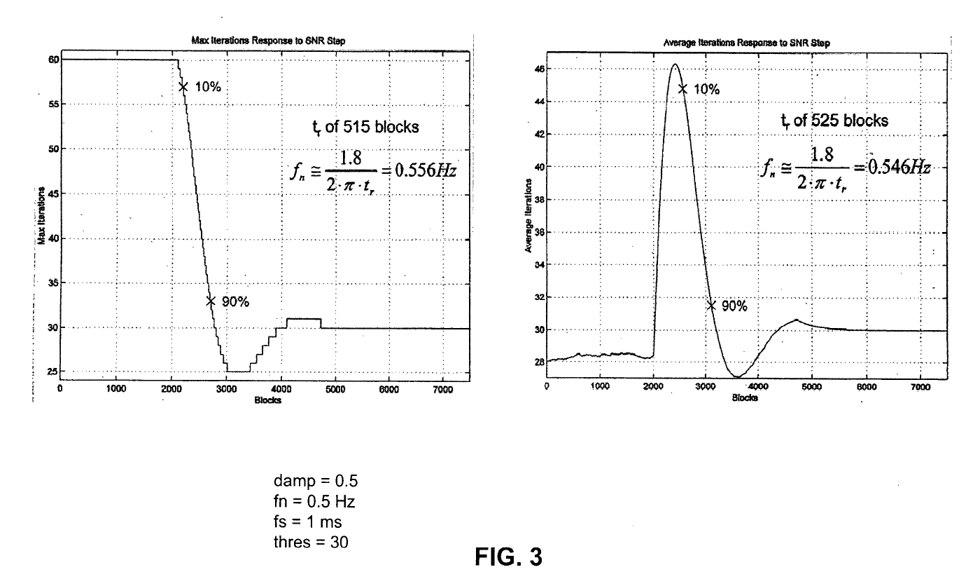

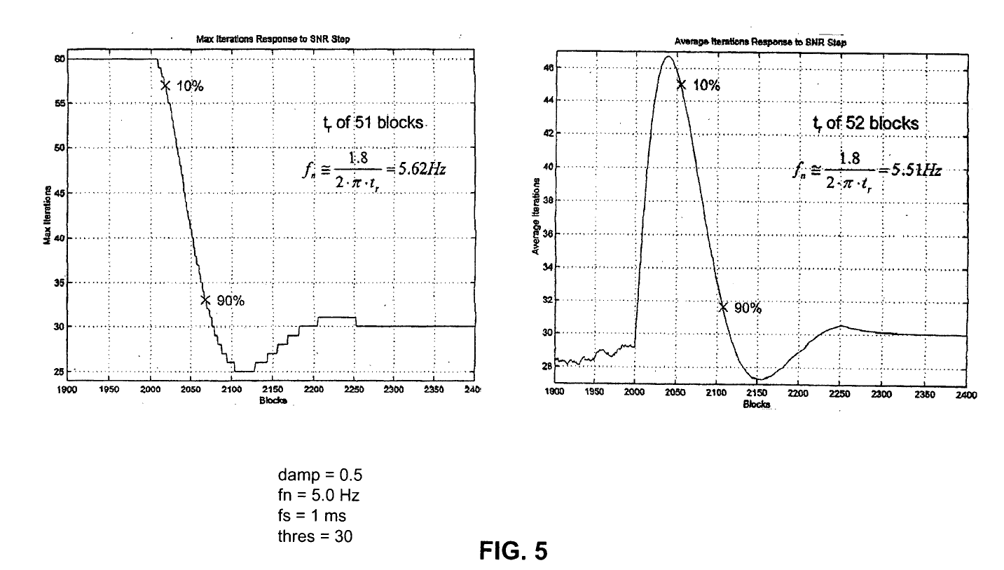

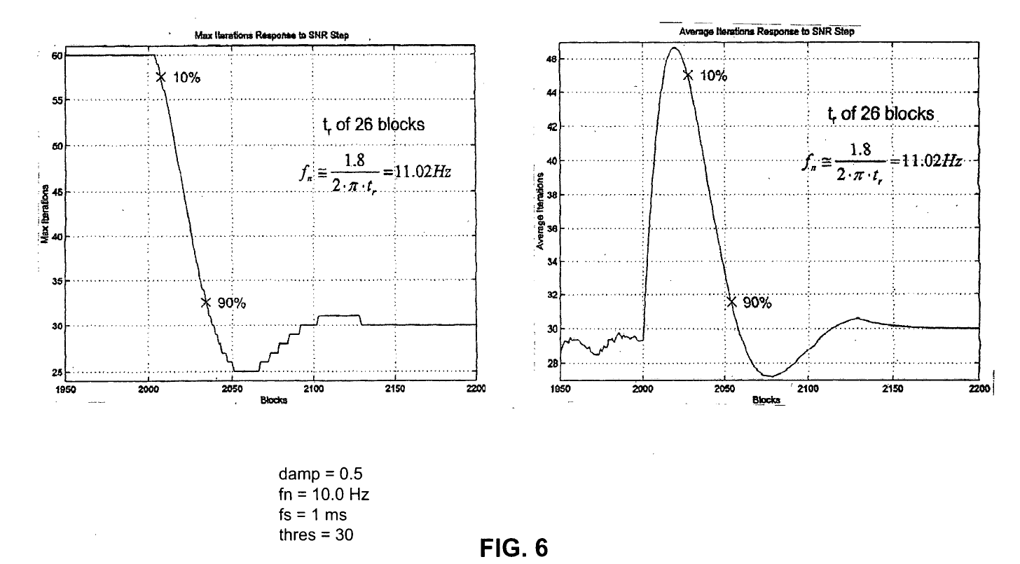

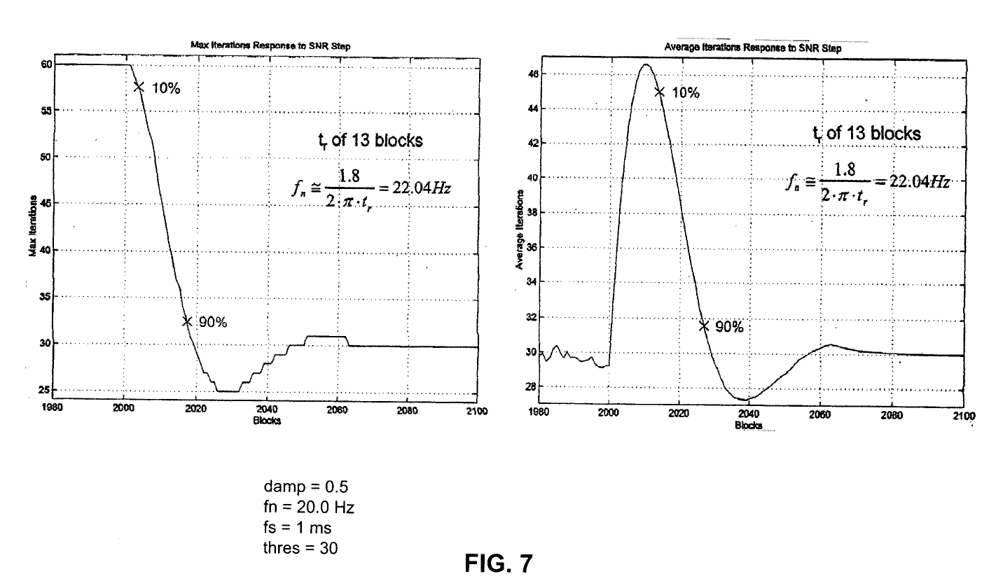

FIGS. 3-7 illustrate the performance of the power savings loop 104 as the loop bandwidth (i.e., fₙ) of the power savings loop 104 is varied. Each of the FIGS. 3-7 illustrates the response of the power savings loop 104 to a unit step function, a conventional technique for characterizing a control loop. For a second-order system, the rise time (response time) can be estimated to be:

$${t}_{r} ≅ \frac{1.8}{{ω}_{n}} \qquad ( Eq . 9 )$$

Eq. 9 allows the response time of the power savings loop 104 to be measured as loop bandwidth is varied.

As an example, the performance of the power savings loop 104 is illustrated in FIG. 3. On the left hand side of FIG. 3, the maximum number of iterations (i.e., the output 124) is compared to the iteration block number. As shown, the maximum number of iterations is initially set to 60 iterations. On the right hand side of FIG. 3, the average number of iterations (the average output 118) is also compared to the iteration block number. The threshold 114 is set to 30. At approximately block 2000, the average number of iterations reported by the averager 106 drastically increases. At approximately block 2300, the peak average number of iterations is greater than 46. When the average number of iterations increases above the threshold at block 2000, the output of the power savings loop 124 is reduced as illustrated on the left hand side of FIG. 3. As shown, the maximum number of allowed iterations is drastically reduced to bring the average number of iterations back down to the threshold of 30 by block 5000.

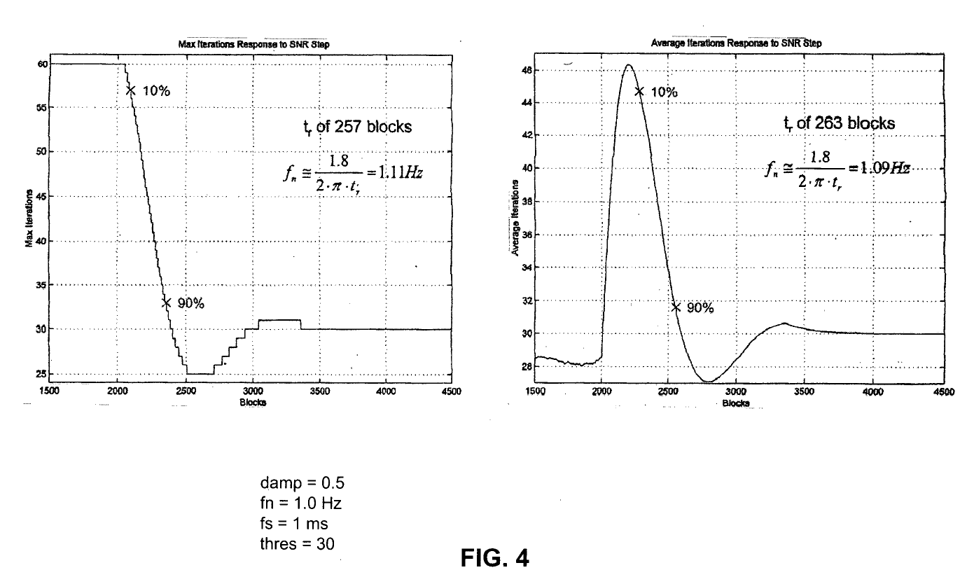

The FIGS. 4-7 are similarly arranged to illustrate the performance of the power savings loop 104 as loop bandwidth is varied.

When the decoder 102 is operating near the threshold 114, the average iteration count 118 will intermittently exceed the threshold 114 and dip below the threshold 114. This causes the power savings loop 104 to turn on and off sporadically. Consequently, the maximum number of permissible iterations 124 will be updated sporadically to adjust the average iteration count 114. In doing so, these overshoots in the adjustment of the average iteration count 118 can frequently occur and can contribute to an increase in the average iteration count 118. Additionally, overshoots of this nature can occur when the power savings loop 104 responds to an initial drop in SNR by quickly decreasing the maximum number of permissible iterations 124.

To limit overshoot and the frequency of overshoot, an aspect of the present invention, in one embodiment, provides for an “excess circuit.” During operation, the excess circuit accumulates a count of the number of blocks that are decoded or processed over a period of time when the average iteration count 118 exceeds the threshold 114. The excess circuit prevents the maximum number of permissible iterations 124 from increasing until the accumulated total or excess has been offset by the decoding of a similar number of blocks for which the average iteration count 118 is below the threshold 114. Once the excess has been “bled off,” the maximum number of permissible iterations 124 is allowed to increase. In this way, the excess circuit of the present invention provides hysteresis for the adjustment of the maximum number of permissible iterations 124.

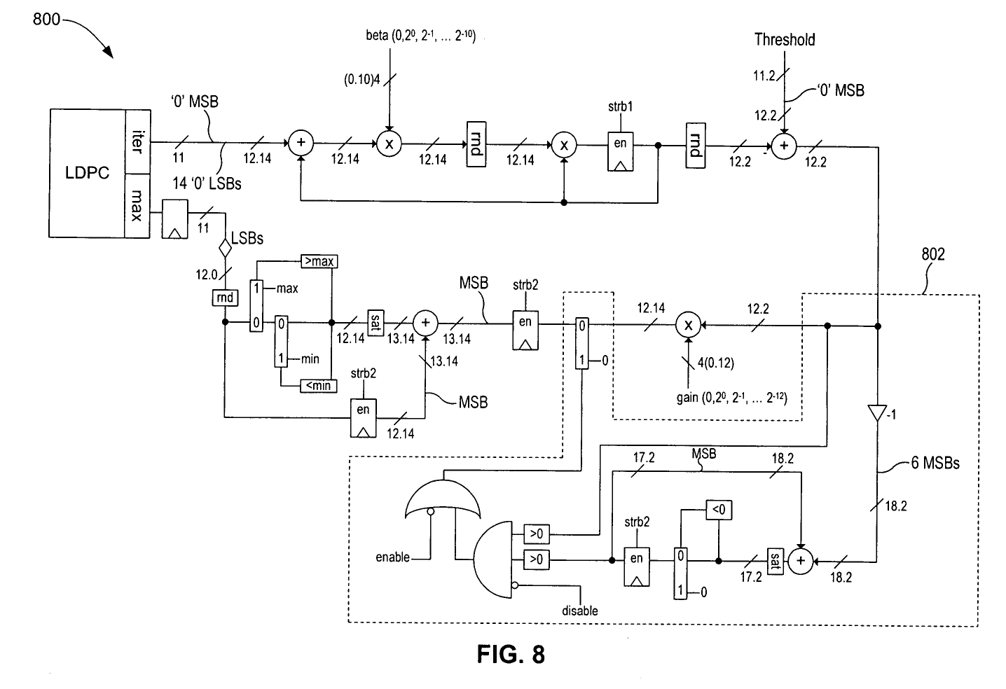

FIG. 8 depicts an embodiment of an excess circuit 802 operating within a decoding system 800 of the present invention. The excess circuit 802 can be implemented with an integrator. As shown in FIG. 8, the excess circuit is coupled to the adder 108 and the programmable gain device 110.

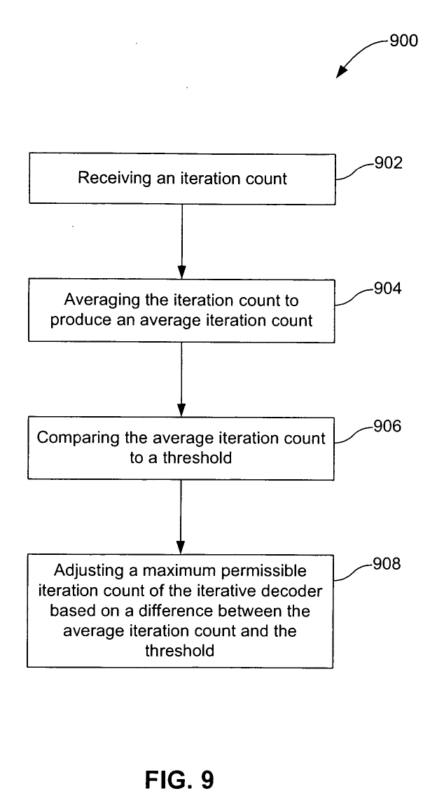

FIG. 9 is a flow diagram of an exemplary method 900 of practicing an embodiment of the present invention. In FIG. 9, an iteration count is received, as indicated in step 902 and the iteration count is averaged to produce an average iteration count, as indicated in step 904. In step 906, the average iteration count is compared to a threshold, as shown in step 906. And in step 908, a maximum permissible iteration count of an iterative decoder is adjusted based on a difference between the average iteration count and the threshold.

It is to be appreciated by one skilled in the art(s) that the power management features provided by an aspect of the present invention are applicable to any iterative decoding process, scheme or circuit.

### Conclusion

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and.the appended claims in any way.

While various embodiments of the present invention have been described above, it should be understood that they have been presented by way of example and not limitation. It will be apparent to one skilled in the pertinent art that various changes in form and detail can be made therein without departing from the spirit and scope of the invention. Therefore, the present invention should only be defined in accordance with the following claims and their equivalents.

What is claimed is:

1. A power control loop for an iterative decoder, comprising:
an averaging device to produce an average iteration count of the iterative decoder;
an adder to compare the average iteration count to a threshold; and
an integrator to adjust a maximum permissible iteration count of the iterative decoder based on an output of the adder.

2. The power control loop of claim 1, wherein the integrator decreases the maximum permissible iteration count when the average iteration count is greater than the threshold.

3. The power control loop of claim 2, wherein the integrator, after decreasing the maximum permissible iteration count, increases the maximum permissible iteration count when the average iteration count is below the threshold.

4. The power control loop of claim 1, further comprising a programmable gain device coupled between the adder and the integrator.

5. The power control loop of claim 4, wherein the programmable gain device amplifies the output of the adder.

6. The power control loop of claim 4, further comprising an excess circuit coupled to the adder and the programmable gain device.

7. The power control loop of claim 6, wherein the excess circuit introduces a hysteresis effect to affect an increase of the maximum permissible iteration count

8. The power control loop of claim 1, further comprising a multiplier coupled between the adder and the integrator.

9. The power control loop of claim 1, wherein the threshold is approximately equal to an average number of iterations executed by the iterative decoder at a quasi-error free (QEF) point.

10. The power control loop of claim 1, wherein the averager includes an integrator with a time constant.

11. The power control loop of claim 1, wherein the iterative decoder is a low-density parity-check (LDPC) decoder.

12. The power control loop of claim 1, wherein the iterative decoder is a turbo code soft-input soft-output (SISO) decoder.

13. A method for reducing an average power consumed by an iterative decoder, comprising:
receiving an iteration count;
averaging the iteration count to produce an average iteration count;
comparing the average iteration count to a threshold; and
adjusting a maximum permissible iteration count of the iterative decoder based on a difference between the average iteration count and the threshold.

14. The method of claim 13, further comprising setting the threshold equal to an average number of iterations implemented by the iterative decoder at a quasi-error free (QEF) point.

15. The method of claim 13, wherein the averaging further comprises computing an average over a programmable number of data blocks.

16. The method of claim 13, wherein adjusting further comprises decreasing the maximum permissible iteration count when the average iteration count is greater than the threshold.

17. The method of claim 16, wherein adjusting further comprises increasing the maximum permissible iteration count, after decreasing the maximum permissible iteration count, when the average iteration count is less than the threshold.
